(19) United States
(12) Patent Application Publication
(10) Pub. No.: US 2010/0132784 A1
(43) Pub. Date: Jun. 3, 2010

(54) DYE SENSITIZED SOLAR CELL WITH SEPARATION MEMBRANE AND METHOD THEREOF

(76) Inventors: Dong Hyon Sheen, Daejeon (KR); Ho Jin Kim, Daejeon (KR)

Correspondence Address: ABELMAN, FRAYNE & SCHWAB, 666 THIRD AVENUE, 10TH FLOOR, NEW YORK, NY, 10017, US

(21) Appl. No.: 12/448,971

(22) PCT Filed: Jan. 16, 2008
(86) PCT No.: PCT/KR2008/000279

§ 371 Date: Dec. 23, 2009

(30) Foreign Application Priority Data
Jan. 16, 2007 (KR) 10-2007-0004767
Jan. 15, 2008 (KR) 10-2008-0004521

(51) Int. Cl. H01L 31/00; H01L 31/18

(52) U.S. Cl. 136/256; 438/57; 257/E31.001; 977/773

(57) ABSTRACT

Disclosed herein is a dye-sensitized solar cell provided with a separation membrane between a photoelectrode and a counter electrode, in which, because the separation membrane serves as a support, it is possible to prevent damage thereto, the shorting between the two electrodes, and the leaning phenomenon of an electrolyte, and in which, because the separation membrane serves as a support, unit cells having large areas can be fabricated, so that the effective area thereof is increased, thereby realizing a highly efficient cell.

### TECHNICAL FIELD

The present invention relates to a dye-sensitized solar cell and a method of manufacturing the same, and more particularly, to a dye-sensitized solar cell provided with a separation membrane between a photoelectrode and a counter electrode, in which, because the separation membrane serves as a support, it is possible to prevent damage thereto, the shorting between the two electrodes, and the leaning phenomenon of an electrolyte, and in which, because the separation membrane serves as a support, unit cells having large areas can be fabricated, so that the effective area thereof is increased, thereby realizing a highly efficient cell.

### BACKGROUND ART

A dye-sensitized solar cell is a third-generation solar cell having higher price competitiveness than a conventional solar cell.

As important factors in solar cells, there are efficiency, durability and price. The durability of a silicon solar cell was accepted in the marketplace, but there is a problem in that it is difficult to increase the competitiveness of solar light energy because the silicon solar cell is more expensive than conventional energy sources.

A silicon solar cell, which is a first-generation solar cell, is used in large scale solar power plants, and is provided on rooftops to supply power. Such a silicon solar cell is problematic in that the shortage of silicon is exacerbated, production costs are high, and production processes are difficult. Therefore, commercialization of a cheap dye-sensitized solar cell, which has competitiveness and is manufactured through processes different from those of the silicon solar cell, is in progress.

That is, a silicon solar cell needs a semiconductor process, and thus there are difficulties, such as the requirement for high temperatures and a vacuum state, in manufacturing the silicon solar cell, and the silicon solar cell also needs expensive silicon raw materials. Therefore, in order to reduce costs of expensive silicon, a thin film type silicon solar cell having a wafer thickness of 200 μm has been developed instead of a silicon solar cell having a wafer thickness of 380 μm, which was made before 200 μm. Furthermore, in order to realize improvement in efficiency and further reduction of costs, it is required to develop an ultra-thin film type silicon solar cell having a wafer thickness below 200 μm. However, in order to manufacture the ultra-thin film type silicon solar cell, development of high level technologies are required, and there is some danger of damage in the manufacturing and mounting processes thereof.

Therefore, a dye-sensitized solar cell is being emphasized as a next-generation solar cell to replace a silicon solar cell.

A dye-sensitized solar cell, unlike a silicon solar cell, is a photoelectrochemical solar cell chiefly including photosensitive dye molecules for forming an electron-hole pair by absorbing visible light and transition metal oxides for transferring electrons that are formed.

Among dye-sensitized solar cells known to date, the representative examples of dye-sensitized solar cells, which were invented by Gratzel et al. in Switzerland, are disclosed in U.S. Pat. Nos. 4,927,721 and 5,350,644. The dye-sensitized solar cell invented by Gratzel et al. includes a semiconductor electrode formed of titanium dioxide (TiO₂) nanoparticles on which dye molecules are adsorbed, a platinum electrode, and an electrolyte solution charged therebetween.

This dye-sensitized solar cell has attracted considerable attention due to the fact that, since its manufacturing cost in relation to power is lower than those of conventional solar cells, it can replace conventional solar cells.

As electrodes of such a dye-sensitized solar cell, conventionally, transparent glass electrodes have been used. However, such transparent glass electrodes are problematic in that they occupy a high percentage of the total costs of raw materials and inhibit the development of flexible solar cells.

That is, the dye-sensitized solar cell is advantageous in that the manufacturing process thereof is simple because a coating process is included, compared to silicon solar cells, but is problematic in that transparent glass electrodes cannot be used when the dye-sensitized solar cell is converted into a flexible dye-sensitized solar cell. As a result, dye-sensitized solar cells using transparent glass electrodes are limited to use in power plants, on rooftops, and the like.

As a conventional technology proposed in order to solve the above problems, a dye-sensitized solar cell using plastic electrodes instead of transparent glass electrodes was disclosed.

As such, when plastic electrodes are used, it is possible to realize a flexible dye-sensitized solar cell that can be put to various practical uses, can be manufactured at low cost, and can be easily manufactured to have a large area.

Generally, solar cells are increasingly used in the fields of large capacity power generation and building materials for outer walls, portable terminals, such as notebook computers, personal digital assistants (PDAs), mobile phones, cameras and the like, and military supplies, such as tents, radio devices and the like.

In the manufacture of solar cells, when small size cells are fabricated and then formed into a module, the effective area of the module is decreased because of insulation parts and electrode connection parts, and the efficiency thereof is decreased due to the increase in resistance of the electrode connection parts. Therefore, when large area cells can be fabricated in the first stage, the effective area thereof is increased, thus preventing the decrease in efficiency.

However, flexible dye-sensitized solar cells are advantageous in that the manufacturing process thereof is very simple due to a coating process, and the process efficiency thereof is also increased with the increase in the area of cells when small size cells are fabricated and then formed into a module at the time of making cells into a module, but are problematic in that it is difficult to fabricate large area cells because of the leaning phenomenon of an electrolyte.

Further, since flexible dye-sensitized solar cells must have a thin film structure, breakage prevention and durability must be ensured. Therefore, there is a problem in that they must have a thin film structure but must also resist breakage, meaning that they must be very durable.

Furthermore, thin film type dye-sensitized solar cells are also problematic in that, since the gap between the two electrodes is narrow, shorts therebetween can occur, thus hindering the development of thinned electrodes.

### DISCLOSURE

### Technical Problem

Accordingly, the present invention has been made keeping in mind the above problems occurring in the prior art, and an object of the present invention is to provide a dye-sensitized solar cell provided with a separation membrane between a photoelectrode and a counter electrode, in which, because the separation membrane serves as a support, damage and the leaning phenomenon of an electrolyte can be prevented, and a method of manufacturing the dye-sensitized solar cell.

Another object of the present invention is to provide a dye-sensitized solar cell provided with a separation membrane between a photoelectrode and a counter electrode, in which, because the separation membrane serves as a support, the shorting between the two electrodes can be prevented, and a method of manufacturing the dye-sensitized solar cell.

A further object of the present invention is to provide a dye-sensitized solar cell provided with a separation membrane between a photoelectrode and a counter electrode, in which, because the separation membrane serves as a support, large area unit cells can be fabricated, and a method of manufacturing the dye-sensitized solar cell.

Yet another object of the present invention is to provide a dye-sensitized solar cell provided with a separation membrane between a photoelectrode and a counter electrode, in which, because the separation membrane serves as a support, a large area cell can be fabricated, so that the effective area thereof is increased, thereby making the solar cell highly efficient.

### Technical Solution

In order to accomplish the above objects, the present invention provides a solar cell, including: a photoelectrode including an oxide nanoparticle layer in which dye is adsorbed on oxide nanoparticles contained therein; a counter electrode disposed to face the photoelectrode; an electrolyte solution charged between the photoelectrode and the counter electrode; and a separation membrane interposed between the photoelectrode and the counter electrode.

Further, the present invention provides a method of manufacturing a solar cell, including: (A) layering a separation membrane on a photoelectrode including an oxide nanoparticle layer; (B) layering a counter electrode on the photoelectrode on which the separation membrane is layered such that the counter electrode faces the photoelectrode, and then sealing the photoelectrode and the counter electrode while forming electrolyte solution injection inlets over and under the separation membrane; and (C) injecting an electrolyte solution through the electrolyte solution injection inlets and then sealing the electrolyte solution injection inlets.

### ADVANTAGEOUS EFFECTS

The dye-sensitized solar cell of the present invention is advantageous in that a separation membrane is provided between a photoelectrode and a counter electrode, and the separation membrane serves as a support, so that stability is increased, thereby improving durability and preventing damage.

Further, the dye-sensitized solar cell of the present invention is advantageous in that a separation membrane is provided between a photoelectrode and a counter electrode, and the separation membrane serves as a support, thus preventing the leaning phenomenon of an electrolyte.

Further, the dye-sensitized solar cell of the present invention is advantageous in that a separation membrane is provided between a photoelectrode and a counter electrode, and the separation membrane serves as a support, thus preventing the shorting between the two electrodes.

Further, the dye-sensitized solar cell of the present invention is advantageous in that a separation membrane is provided between a photoelectrode and a counter electrode, and the separation membrane serves as a support, thus fabricating large area unit cells.

Further, the dye-sensitized solar cell of the present invention is advantageous in that a separation membrane is provided between a photoelectrode and a counter electrode, and the separation membrane serves as a support, and a large area cell can be fabricated, so that the effective area thereof is increased, thereby causing the cell to have high efficiency.

### DESCRIPTION OF DRAWINGS

FIG. 1 is a sectional view showing the structure of a dye-sensitized solar cell according to an embodiment of the present invention; and

FIGS. 2 to 6 are views showing a method of manufacturing the dye-sensitized solar cell according to an embodiment of the present invention.

### DESCRIPTION OF THE ELEMENTS IN THE DRAWINGS

100: photoelectrode
102: first substrate
104: transparent conductive electrode
106: first conductive substrate
120: dye-adsorbed oxide nanoparticles
140: electrolyte solution
160: separation membrane
180: counter electrode
182: second substrate
184: platinum layer
186: second conductive substrate
190: epoxy resin

### BEST MODE

Hereinafter, a dye-sensitized solar cell and a method of manufacturing the dye sensitized solar cell according to an embodiment of the present invention will be described with reference to the attached drawings.

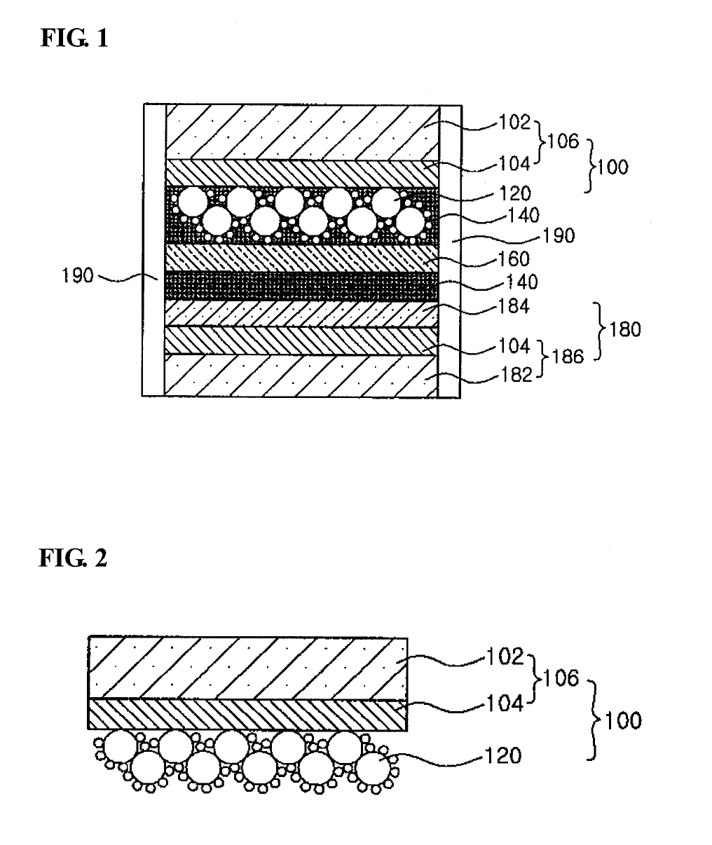

FIG. 1 is a sectional view showing the structure of a dye-sensitized solar cell according to an embodiment of the present invention.

Referring to FIG. 1, the dye-sensitized solar cell according to an embodiment of the present invention includes a photoelectrode 100, an electrolyte solution 140, a separation membrane 160, a counter electrode 180, and an epoxy resin 190.

Here, the photoelectrode 100 includes a first substrate 102, which is conductive, flexible and optically transparent, a transparent conductive electrode 104 applied on the first substrate 102, and an oxide nanoparticle layer 120, in which dye is adsorbed on oxide nanoparticles contained therein, and which is adhered on the transparent conductive electrode 104.

In this case, a first conductive substrate 106 may be formed by coating a first substrate 102 made of a transparent polymer plate, such as polyethylene terephthalate (PET), polycarbonate, polyimide, polyethylene naphthalate or polyether sulfone (PES), with a transparent conductive electrode 104, such as indium tin oxide (ITO) or fluoride tin oxide (FTO), which is fluorine-doped tin dioxide. Alternatively, the first conductive substrate 106 may be formed of conductive plastic. Polyethylene terephthalate (PET) has excellent heat resistance, elasticity and water resistance, compared to other materials. Polycarbonate has good dimensional stability, optical transparency, and particularly, excellent impact resistance. Polyethylene naphthalate also has excellent water resistance and moisture proofness.

Next, the oxide nanoparticle layer 120 is formed on the first conductive substrate 106 at a thickness of 5˜15 μm, and has dye molecules composed of ruthenium (Ru) complex chemically adsorbed thereon. The oxide nanoparticle layer 120, in which dye is adsorbed on oxide nanoparticles contained therein, may be a titanium dioxide layer, a tin dioxide layer or a zinc oxide layer.

The electrolyte solution 140 may be an I₃⁻/I⁻ electrolyte solution formed by dissolving 8M of 1,2-dimethyl-3-octyl-imidazolium iodide, which is an iodine-base oxidation-reduction liquid electrolyte, and 40 mM of I₂(Iodine) in 3-Methoxypropionitrile, or ionic liquids may be used as the electrolyte solution 140.

Meanwhile, the counter electrode 180 is disposed to face the photoelectrode 100, and is formed by coating a second conductive substrate 186, which is conductive and flexible, with a platinum layer 184. In this case, the second conductive substrate 186 may be formed by coating a second substrate 182, made of a transparent polymer plate, such as polyethylene terephthalate (PET), polycarbonate, polyimide, polyethylene naphthalate or polyether sulfone (PES), with a transparent conductive electrode 104, such as indium tin oxide (ITO) or fluoride tin oxide (FTO), which is fluorine-doped tin dioxide. Alternatively, the second conductive substrate 186 may be formed of conductive plastic. Further, a thin metal plate, such as aluminum or stainless steel, may be used as the second substrate 182.

The platinum layer 184 may be formed by preparing the above polymer plate; dispersing 5 mM of a hexachloroplatinic acid (H₂PtCl₆.xH₂O) solution on the polymer plate and then drying it, thus coating the polymer plate with platinum ions; treating the polymer plate coated with platinum ions using 60 mM of sodium borohydride (NaBH4) solution, thus reducing platinum ions to platinum; and washing the polymer plate using distilled water and then drying it.

The separation membrane 160 is disposed between the photoelectrode 100 and the counter electrode 180, and is formed of an ion-permeable membrane.

This separation membrane 160 may have a thickness of 100 μm or less, and may include one or more selected from among polyethylene, polypropylene, polyimide, cellulose, polyvinyl chloride (PVC), polyvinyl alcohol and Polyvinylidene difluoride (PVDF), or may be a thin polymer separation membrane.

Here, the separation membrane 160, serving as a support, can prevent damage, the leaning phenomenon of the electrolyte solution 140, and the shorting between the two electrodes.

Further, the separation membrane 160, serving as a support, enables a basic cell of a dye-sensitized solar cell to be fabricated to have a large area.

The large area basic cell increases the effective area of the dye-sensitized solar cell, so that the decrease of efficiency is prevented, thereby ultimately fabricating a dye-sensitized solar cell having high efficiency.

Further, the separation membrane 160 is inserted in the dye-sensitized solar cell, so that damage to the dye-sensitized solar cell is prevented, thereby improving durability.

Further, the entire oxide nanoparticle layer 120 in which dye is adsorbed on oxide nanoparticles contained therein and part of the electrolyte solution 140 may be disposed between the separation membrane 160 and the first conductive substrate 106, and the remainder of the electrolyte solution 140 may be disposed between the separation membrane 160 and the counter electrode 180. Meanwhile, the epoxy resin 190 surrounds and seals a laminate including a photoelectrode 140, an oxide nanoparticle layer 120 in which dye is adsorbed on oxide nanoparticles contained therein, an electrolyte 140, a separation membrane 160 and a counter electrode 180.

The operation of the dye-sensitized solar cell according to the present invention is as follows.

When the dye molecules adsorbed on an oxide nanoparticle layer 120 absorb the light that has passed through a first conductive substrate 106 of a photoelectrode 100, the dye molecules are changed from a ground state to an excited state, so as to form electron-hole pairs, and electrons in the excited state are injected into a conduction band of the oxide nanoparticle layer 120.

The electrons injected into the oxide nanoparticle layer 120 are transferred to the first conductive layer 106 adjacent to the oxide nanoparticle layer 120 through an interparticle interface, and simultaneously move to a second conductive substrate 186 through external electric wires (not shown).

The dye molecules, oxidized due to the transition of electrons, receive the electrons generated by the oxidation (3I⁻-->I⁻₃-62e⁻) of iodine ions in the electrolyte solution 140 present between the first conductive substrate 106 and the separation membrane 160, and are thus reduced again.

Subsequently, the oxidized iodine ions (I⁻₃) move to the space between the separation membrane 160 and the counter electrode 180, and are then reduced into the iodine ions (3I⁻) by the electrons having reached the counter electrode 180, thus completing the mechanism for operating the dye-sensitized solar cell.

FIGS. 2 to 6 are views showing a method of manufacturing the dye-sensitized solar cell according to an embodiment of the present invention.

Referring to FIG. 2, a photoelectrode 100 is completed by forming an oxide nanoparticle layer 120, in which dye is adsorbed on oxide nanoparticles contained therein, on a first conductive substrate 106 including a first substrate 102 coated with a transparent conductive electrode 104.

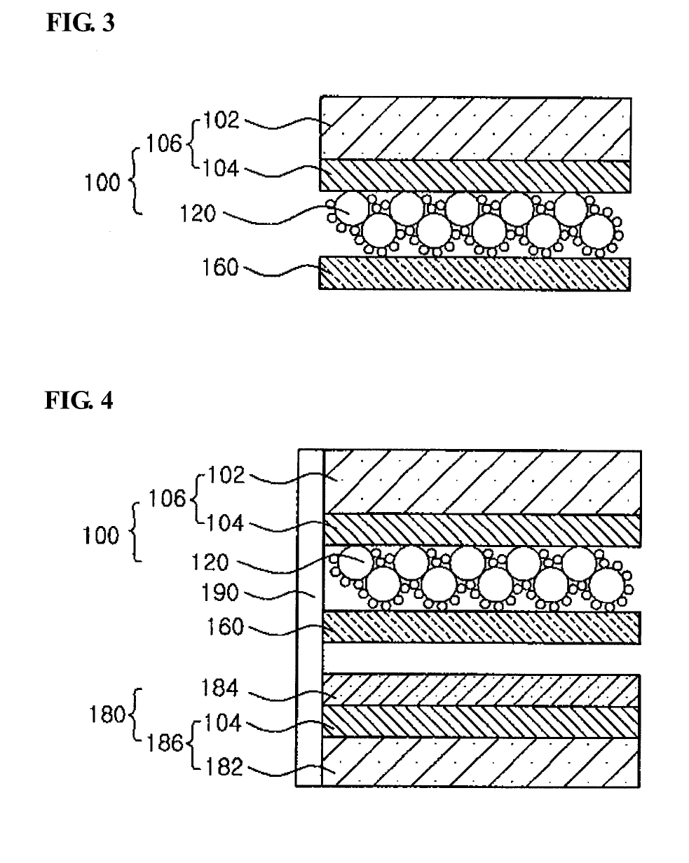

Referring to FIG. 3, a separation membrane 160 is layered on the oxide nanoparticle layer 120 of the photoelectrode 100.

Subsequently, referring to FIG. 4, a counter electrode 180, formed by coating a second conductive substrate 186 with a platinum layer 184, the second conductive substrate 186 first formed by coating a second substrate 182 with a transparent conductive electrode 104, is joined to the photoelectrode 100 such that the counter electrode 180 faces the photoelectrode 100, and then the one side of the photoelectrode 100 and the counter electrode 180 is fixed with an epoxy resin 190 while an electrolyte injection inlet is left open.

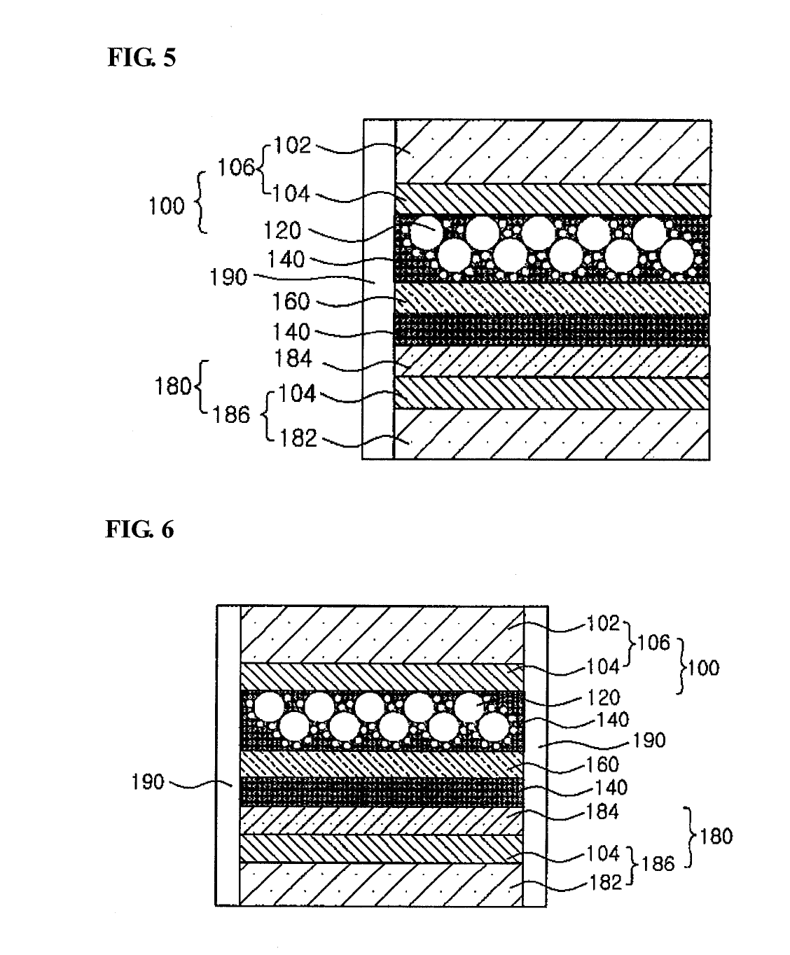

Finally, referring to FIG. 5, an electrolyte solution 140 is charged in the upper and lower space of the separation membrane 160 through the electrolyte injection inlet, and then, as shown in FIG. 6, the other side of the photoelectrode 100 and the counter electrode 180 is sealed, thereby completing the dye-sensitized solar cell of the present invention.

1. A solar cell, comprising:
a photoelectrode including an oxide nanoparticle layer in which dye is adsorbed on oxide nanoparticles contained therein;
a counter electrode disposed to face the photoelectrode;
an electrolyte solution charged between the photoelectrode and the counter electrode; and
a separation membrane interposed between the photoelectrode and the counter electrode.

2. The solar cell according to claim 1, wherein the photoelectrode comprises a first conductive substrate having optical transparency and flexibility, and the oxide nanoparticle layer formed on the first conductive substrate, in which dye is adsorbed on oxide nanoparticles contained in the oxide nanoparticle layer.

3. The solar cell according to claim 1, wherein the counter electrode comprises a second conductive substrate having flexibility, and a platinum layer formed on the second conductive substrate.

4. The solar cell according to claim 1, wherein the counter electrode includes a metal plate made of any one of aluminum and stainless steel.

5. The solar cell according to claim 2, wherein the first conductive substrate of the photoelectrode comprises a first substrate made of a transparent polymer, such as polyethylene terephthalate (PET), polycarbonate, polyimide, polyethylene naphthalate, or polyether sulfone (PES), and a transparent electrode applied on the first substrate and made of indium tin oxide (ITO) or fluorine-doped tin dioxide (FTO, fluoride tin oxide) and a transparent conductive material.

6. The solar cell according to claim 2, wherein the first conductive substrate of the photoelectrode is made of conductive plastic.

7. The solar cell according to claim 3, wherein the second conductive substrate of the counter electrode comprises a second substrate made of a transparent polymer, such as polyethylene terephthalate (PET), polycarbonate, polyimide, polyethylene naphthalate, or polyether sulfone (PES), and a transparent electrode applied on the second substrate and made of indium tin oxide (ITO) or fluorine-doped tin dioxide (FTO, fluoride tin oxide) and a transparent conductive material.

8. The solar cell according to claim 3, wherein the second conductive substrate of the counter electrode is made of conductive plastic.

9. The solar cell according to claim 1, wherein the electrolyte solution includes an iodine-based oxidation-reduction liquid electrolyte solution or an ionic liquid including an ionic liquid electrolyte for causing an oxidation-reduction reaction.

10. The solar cell according to claim 1, wherein the separation membrane has a thickness of 100 μm or less.

11. The solar cell according to claim 1, wherein the separation membrane includes one or more selected from among polyethylene, polypropylene, polyimide, cellulose, polyvinyl chloride (PVC), polyvinyl alcohol and polyvinylidene difluoride (PVDF), or includes a thin polymer separation membrane.

12. The solar cell according to claim 1, wherein the separation membrane includes an ion-permeable membrane through which ions of the electrolyte solution permeate.

13. A method of manufacturing a solar cell, comprising:
(A) layering a separation membrane on a photoelectrode including an oxide nanoparticle layer;
(B) layering a counter electrode on the photoelectrode on which the separation membrane is layered such that the counter electrode faces the photoelectrode, and then sealing the photoelectrode and the counter electrode while forming electrolyte solution injection inlets over and under the separation membrane; and
(C) injecting an electrolyte solution through the electrolyte solution injection inlets and then sealing the electrolyte solution injection inlets.

14. The method according to claim 13,
wherein (A) the layering of the separation membrane includes:
forming an oxide nanoparticle layer, which includes oxide nanoparticles having dye adsorbed thereon, on a first conductive substrate; and
layering the separation membrane on the first conductive substrate on which the oxide nanoparticle layer is formed.

15. The method according to claim 13,
wherein (B) the layering of the counter electrode includes:
layering the counter electrode on the photoelectrode having the separation membrane layered thereon such that the counter electrode faces the photoelectrode;
separating the photoelectrode and the counter electrode using the separation membrane; and
sealing a peripheral area of the photoelectrode and the counter electrode while forming the electrolyte solution injection inlet.
